(19) United States
(12) Patent Application Publication
(10) Pub. No.: US 2025/0233051 A1
(43) Pub. Date: Jul. 17, 2025

(54) MULTIPLE CHIP MODULE DIRECT ATTACH COOLING

(71) Applicant: INTERNATIONAL BUSINESS MACHINES CORPORATION, ARMONK, NY (US)

(72) Inventor: MARK D. SCHULTZ, OSSINING, NY (US)

(21) Appl. No.: 18/414,517

(22) Filed: Jan. 17, 2024

(51) Int. Cl. H01L 23/46; H01L 25/065

(52) U.S. Cl. CPC H01L 23/46; H01L 25/0655

(57) ABSTRACT

An apparatus includes a manifold body including a plurality of heat transfer structures therein. The plurality of heat transfer structures are configured to be thermally coupled to a plurality of heat generating components. The apparatus further includes a plurality of flow directing structures within the manifold body. The plurality of flow directing structures configured to direct a first portion of a fluid flow within the manifold body to a first heat transfer structure of the plurality of heat transfer structures and a second portion of the fluid flow within the manifold body to a second heat transfer structure of the plurality of heat transfer structures.

### BACKGROUND

The present disclosure relates to methods, apparatus, and products for multiple chip module direct attach cooling.

### SUMMARY

According to embodiments of the present disclosure, various methods, apparatus and products for multiple chip module direct attach cooling are described herein. In some aspects, multiple chip module direct attach cooling includes an apparatus that includes a manifold body including a plurality of heat transfer structures therein. The plurality of heat transfer structures are configured to be thermally coupled to a plurality of heat generating components. The apparatus further includes a plurality of flow directing structures within the manifold body. The plurality of flow directing structures configured to direct a first portion of a fluid flow within the manifold body to a first heat transfer structure of the plurality of heat transfer structures and a second portion of the fluid flow within the manifold body to a second heat transfer structure of the plurality of heat transfer structures.

### BRIEF DESCRIPTION OF THE DRAWINGS

FIG. 1 sets forth a top view of an example multiple chip module according to aspects of the present disclosure.

FIG. 2 sets forth a top view of a conventional sawn channel cooling device according to aspects of the present disclosure.

FIG. 3 sets forth a top view of an example cooling device for a multiple chip module according to aspects of the present disclosure.

FIG. 4 sets forth a side view of the example cooling device of FIG. 3 according to aspects of the present disclosure.

FIG. 5 sets forth a top view of another example cooling device for a multiple chip module according to aspects of the present disclosure.

FIG. 6 sets forth a flow chart of an example process for multiple chip module direct attach cooling according to aspects of the present disclosure.

### DETAILED DESCRIPTION

Computer systems typically include a combination of hardware and software components, application programs, operating systems, processors, buses, memory, input/output devices, and so on. As advances in semiconductor processing and computer architecture push the performance of the computer higher and higher, more sophisticated computer software has evolved to take advantage of the higher performance of the hardware, resulting in computer systems today that are much more powerful than just a few years ago. With the increase in performance of computer system hardware, the need to remove heat from heat generating components such as processors, for example central processing units (CPUs) and graphics processing units (GPUs), is becoming increasingly more important. Thermal cooling solutions are usually employed to assist in heat removal from processors. Often one or more cooling elements are thermally coupled to the heat generating component, such as processor cores, to dissipate heat generated by the component. Such cooling elements include, for example, cold plates, heat sinks, fluid cooling systems (e.g., water cooling systems), vapor chambers, heat pipes, fans, and the like to conduct heat to dissipate the heat out of the computing device. However, existing solutions may not adequately cool components of a computing system.

Compliant cold plate technology has been utilized as a thermal cooling solution for large die packages such as large Single Chip Modules (SCMs), Dual Chip modules (DCMs), and Multi-Chip Modules (MCMs). MCMs often include both high performance cores and low performance cores. Compliant cold plates include a compressible layer that drives the compliant cold plate to conform to dimensional differences between the cold plate and the heat generating component being cooled. Compliance is important for system reliability and consistent thermal performance across large die (e.g., SCM, DCM, and MCM) packages.

Current Dual Chip modules are typically cooled using compliant direct attach cooling in which compliant cold plates are directly attached to the chip modules to be cooled. The cold plates for these modules can be implemented in multiple ways including options which flow coolant across (e.g., perpendicular to) a row of high performance cores. One conventional option is to utilize standard sawn channels in the cold plate to flow coolant in this way. Alternately, the coolant may flow through mesh structures within the cold plate. The arrangement of high performance cores in rows rather than some other more thermally preferable arrangement such as a checkerboard pattern is a requirement of some base chip designs which cannot be changed without significantly affecting system performance. Some emerging MCM designs, such as Quad Chip Module (QCM) designs utilize core configurations which place chips with these rows of cores next to each other but with the cores of neighboring chips oriented orthogonally with respect to each other. With coolant flow in one direction, coolant will flow along the core row for some of the chips, resulting in large preheat and substantially elevated downstream core temperatures which may be unacceptable in product implementation. QCM designs typically have areas to be cooled that are large in both directions compared to DCM designs where one dimension is much larger than the other. Compliant direct attach utilizes flexibility in the cold plate to create a mechanically reliable thermal solution. Sawn channel type cold plates are much stiffer along the channel direction. As a result, increasing this dimension as would be required for a QCM may be problematic for reliability as well as thermal performance.

Various embodiments described herein provide for cold plates with high performance heat transfer structures providing cooling zones over the cores of a chip and utilize lower performing structures elsewhere to simultaneously cool low power areas and route coolant to high performance zones such that cooling flows perpendicular to core rows in these areas.

In one or more embodiments, a manifold body or other container is provided that includes a number of heat transfer structures within the manifold body that are configured to be thermally coupled to a number of heat generating components of a multiple chip module. A heat transfer structure is a structure configured to transfer heat from the heat generating components into a coolant. In one or more embodiments, this coolant is flowing within the manifold body. In particular embodiments, the manifold body is configured to be directly coupled, generally with a thermal interface material (TIM), to the heat generating components. In particular embodiments, the manifold body is configured to contain a flow of heat transfer fluid to facilitate cooling of electronic components. In a particular embodiment, the manifold body forms a cold plate. In particular embodiments, one or more of the heat generating components are chips such as processors, memory, or other electronic components. In particular embodiments, one or more of the heat generating components are arranged orthogonally with respect to another of the heat generating components. A number of flow directing structures (or flow blockers) are provided within the manifold body configured to direct a first portion of a fluid flow within the manifold body to a first heat transfer structure of the number of heat transfer structures and a second portion of the fluid flow within the manifold body to a second heat transfer structure of the number of heat transfer structures. In some implementations, the fluid flow within the manifold body is split and directed to higher heat load portions of the chips of the multiple chip module (e.g., processor cores) before being directed to lower heat load portions of the chips. For example, in particular embodiments, plenums and other non-high-performance zones are configured to direct flow where it is desired while providing adequate cooling for low power chip areas within lower performance mesh or an open plenum.

In some implementations, the manifold body is configured to be compliant under a distributed pressure load when thermally coupled to the heat generating components to allow the manifold body to conform to the top surfaces of the chips of the multiple chip module to increase thermal transfer. In particular embodiments, the flow directing structures are constructed in a mesh type technology either as somewhat rigid walls or as structures that have a high permeability (e.g., with small holes) but remain somewhat flexible. In some implementations, the heat transfer structures are configured to distribute a mechanical load from a first side of the manifold body to a second side of the manifold body. In particular implementations, one or more of the heat transfer structures may have a different heat transfer characteristics and/or a different pressure drop characteristic than others of the heat transfer structures.

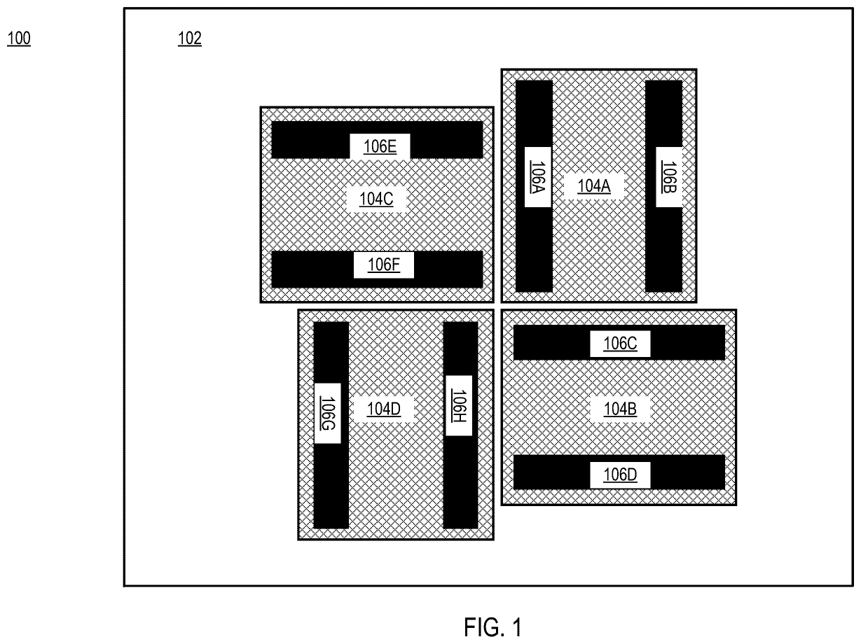

With reference now to FIG. 1, FIG. 1 sets forth a top view of an example multiple chip module 100 according to aspects of the present disclosure. The multiple chip module 100 includes a substrate 102 having a first heat generating component 104A, a second heat generating component 104B, a third heat generating component 104C, and a fourth heat generating component 104D mounted thereon. In a particular embodiment, the substrate 102 includes one or more laminate layers. In particular embodiments, each of the first heat generating component 104A, the second heat generating component 104B, the third heat generating component 104C, and the fourth heat generating component 104D are a chip including a processor or other electronic device. The first heat generating component 104A includes a first core area 106A and a second core area 106B, and the second heat generating component 104B includes a third core area 106C and a fourth core area 106D. The third heat generating component 104C includes a fifth core area 106E and a sixth core area 106F, and the fourth heat generating component 104D includes a seventh core area 106G and an eight core area 106H. In particular embodiments, each of the core areas 106A-106H are higher performing portions that generate a greater amount of heat.

In the particular embodiment shown in FIG. 1, the first heat generating component 104A is arranged orthogonally with respect to the second heat generating component 104B and the third heat generating component 104C. Although various embodiments are described in as having four chips in a multiple chip module, it should be understood that other embodiments may have any number of chips within a multiple chip module.

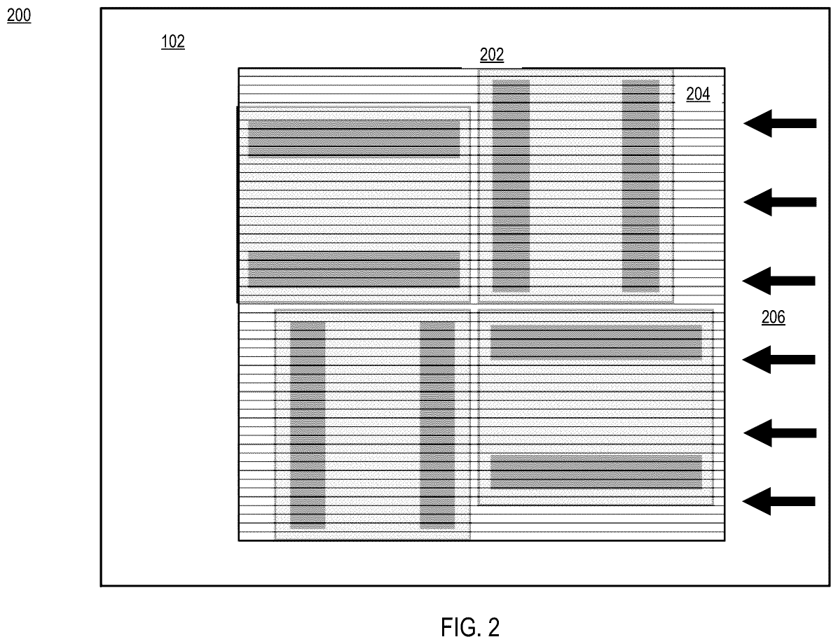

FIG. 2 sets forth a top view of a conventional sawn channel cooling device 200 according to aspects of the present disclosure. The conventional sawn channel cooling device 200 includes a manifold body 202 disposed on the multiple chip module 100 of FIG. 1. The manifold body 202 includes a number of sawn channels 204 for passing a fluid flow 206 for cooling the heat generating components 104A-104D (not shown) of the multiple chip module 100. The sawn channels 204 are constructed of a rigid material often formed from removal of portions of the manifold body 202 to form fluid channels. In the example of FIG. 2, the flow 206 receives heat removed from the first heat generating component 104A before the flow 206 is provided to the third heat generating component 104C. Similarly, the flow 206 receives heat removed from the second heat generating component 104B before the flow 206 is provided to the fourth heat generating component 104D. As a result, the third heat generating component 104C and the fourth heat generating component 104D may not receive adequate cooling. In addition, the rigid nature of the sawn channels 204 may reduce the compliance of the manifold body 202 with the heat generating component 104A-104D resulting in poor heat transfer from the heat generating components and inadequate cooling.

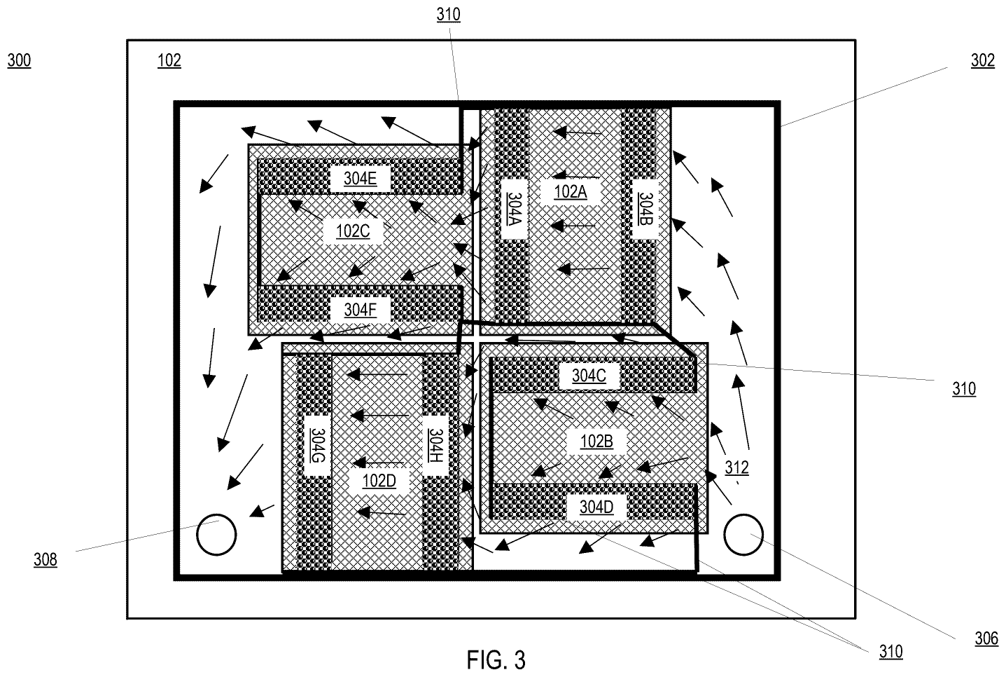

FIG. 3 sets forth a top view of an example cooling device 300 for a multiple chip module according to aspects of the present disclosure. The cooling device 300 includes a manifold body 302 disposed on the multiple chip module 100 of FIG. 1. The manifold body 302 includes a plurality of heat transfer structures 304A-304H within the manifold body 302. The plurality of heat transfer structures 304A-304H are configured to be thermally coupled to the plurality of heat generating components 102A-102D. In the illustrated embodiment, a first heat transfer structure 304A and a second heat transfer structure 304B are configured to be thermally coupled to the core areas of first heat generating component 102A, a third heat transfer structure 304C and a fourth heat transfer structure 304D are configured to be thermally coupled to the core areas of second heat generating component 102B, a fifth heat transfer structure 304E and a sixth heat transfer structure 304F are configured to be thermally coupled to the core areas of third heat generating component 102C, and a seventh heat transfer structure 304G and an eighth heat transfer structure 304H are configured to be thermally coupled to the core areas of first heat generating component 102A.

The heat transfer structures 304A-304H are configured to remove a portion of heat from the high heat load areas (e.g., core areas) of the heat generating components 102A-102D and transfer the portion of heat to the heat transfer fluid. In a particular embodiment, one or more of the heat transfer structures 304A-304H has a different heat transfer characteristic than one or more of the other heat transfer structures 304A-304H. In another particular embodiment, one or more of the heat transfer structures 304A-304H has a different pressure drop characteristic than one or more of the other heat transfer structures 304A-304H.

The manifold body 302 includes a manifold inlet 306 for receiving an input of fluid into the manifold body 302, and a manifold outlet 308 for outputting the fluid. In the example illustrated in FIG. 3, the manifold inlet 306 and the manifold outlet 308 are located on a same side of the manifold body 302. The manifold body 302 includes a plurality of flow directing structures 310 within the manifold body 302. A portion of the flow directing structures 310 are configured to direct a first portion of a fluid flow 312 received from the manifold inlet 306 within the manifold body 302 to the first heat transfer structure 304A and the second heat transfer structure 304B of the first heat generating component 102A, and a second portion of the fluid flow 312 to the third heat transfer structure 304C and the fourth heat transfer structure 304D of the second heat generating component 102B. In a particular embodiment, one or more of the flow directing structures 310 comprises a permeable mesh. In another particular embodiment, one or more of the flow directing structures 310 comprises a rigid or semi-rigid wall.

After the first portion of the flow 312 receives heat from the first heat generating component 102A, a portion of the flow directing structures 310 further direct the first portion of the flow to the fifth heat transfer structure 304E and the sixth heat transfer structure 304F of the third heat generating component 102C. After the second portion of the flow 312 receives heat from the second heat generating component 102B, a portion of the flow directing structures 310 further direct the second portion of the flow to the seventh heat transfer structure 304G and the eighth heat transfer structure 304H of the fourth heat generating component 102D. In particular embodiments, one or more of the flow directing structures 310 further includes one or more openings in a wall of the flow direction structure 310 to allow a portion of heat transfer fluid to pass through to prevent or mitigate stagnation of the flow of the heat transfer fluid.

After removing a portion of heat from each of the first heat generating component 102A, the second heat generating component 102B, the third heat generating component 102C, and the fourth heat generating component 102D, the flow 312 is then directed to the manifold outlet 308. In one or more embodiments, the heat transfer fluid from the manifold outlet 308 is transferred to a cooling component, such as a radiator, to remove a portion of the heat transferred to the heat transfer fluid, and the heat transfer fluid is returned to the manifold inlet 306.

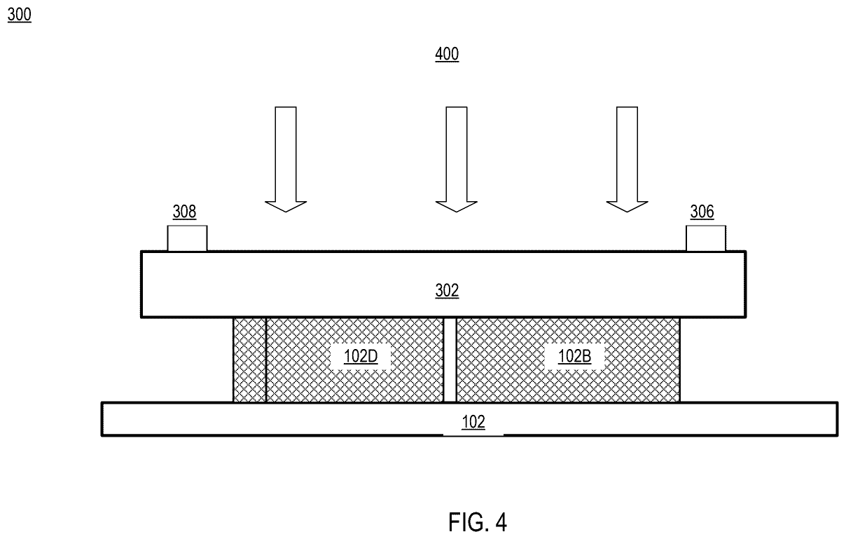

FIG. 4 sets forth a side view of the example cooling device 300 of FIG. 3 according to aspects of the present disclosure. As shown in FIG. 4, the manifold body 302 is configured to be compliant under a distributed pressure load 400 to increase contact with the heat generating components 102A-102D, for example, by a load plate coupled to the manifold body 302 by a compressible layer or other distributed pressure source.

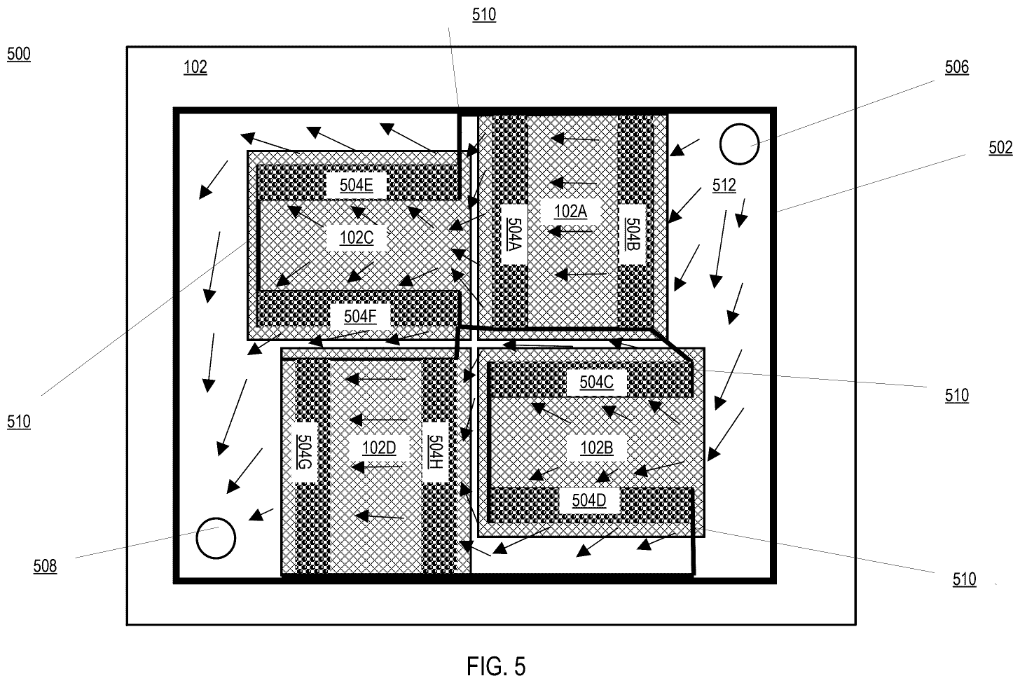

FIG. 5 sets forth a top view of another example cooling device 500 for a multiple chip module according to aspects of the present disclosure. The cooling device 500 includes a manifold body 502 disposed on the multiple chip module 100 of FIG. 1. The manifold body 502 includes a plurality of heat transfer structures 504A-504H within the manifold body 502. The plurality of heat transfer structures 504A-504H are configured to be thermally coupled to the plurality of heat generating components 102A-102D. In the illustrated embodiment, a first heat transfer structure 504A and a second heat transfer structure 504B are configured to be thermally coupled to the core areas of first heat generating component 102A, a third heat transfer structure 504C and a fourth heat transfer structure 504D are configured to be thermally coupled to the core areas of second heat generating component 102B, a fifth heat transfer structure 504E and a sixth heat transfer structure 504F are configured to be thermally coupled to the core areas of third heat generating component 102C, and a seventh heat transfer structure 504G and an eighth heat transfer structure 504H are configured to be thermally coupled to the core areas of first heat generating component 102D.

The heat transfer structures 504A-504H are configured to remove a portion of heat from the high heat load areas (e.g., core areas) of the heat generating components 102A-102D and transfer the portion of heat to the heat transfer fluid. In a particular embodiment, one or more of the heat transfer structures 504A-504H has a different heat transfer characteristic than one or more of the other heat transfer structures 504A-504H. In another particular embodiment, one or more of the heat transfer structures 504A-504H has a different pressure drop characteristic than one or more of the other heat transfer structures 504A-504H.

The manifold body 502 includes a manifold inlet 506 for receiving an input of fluid into the manifold body 502, and a manifold outlet 508 for outputting the fluid. In the example illustrated in FIG. 5, the manifold inlet 506 and the manifold outlet 508 are located at diagonal corners of the manifold body 502. In particular embodiments, the diagonal locations of the manifold inlet 506 and the manifold outlet 508 may allow for more symmetric flow of heat transfer fluid than that described with respect to FIG. 3. The manifold body 502 includes a plurality of flow directing structures 510 within the manifold body 502. A portion of the flow directing structures 510 are configured to direct a first portion of a fluid flow 512 received from the manifold inlet 506 within the manifold body 302 to the first heat transfer structure 504A and the second heat transfer structure 504B of the first heat generating component 102A, and a second portion of the fluid flow 512 to the third heat transfer structure 504C and the fourth heat transfer structure 504D of the second heat generating component 102B. In a particular embodiment, one or more of the flow directing structures 510 comprises a permeable mesh. In another particular embodiment, one or more of the flow directing structures 510 comprises a rigid or semi-rigid wall.

After the first portion of the flow 512 receives heat from the first heat generating component 102A, a portion of the flow directing structures 510 further direct the first portion of the flow to the fifth heat transfer structure 504E and the sixth heat transfer structure 504F of the third heat generating component 102C. After the second portion of the flow 512 receives heat from the second heat generating component 102B, a portion of the flow directing structures 510 further direct the second portion of the flow to the seventh heat transfer structure 504G and the eighth heat transfer structure 504H of the fourth heat generating component 102D. In particular embodiments, one or more of the flow directing structures 510 further includes one or more openings in a wall of the flow directing structure 510 to allow a portion of heat transfer fluid to pass through to prevent or mitigate stagnation of the flow of the heat transfer fluid.

After removing a portion of heat from each of the first heat generating component 102A, the second heat generating component 102B, the third heat generating component 102C, and the fourth heat generating component 102D, the flow 512 is then directed to the manifold outlet 508. In one or more embodiments, the heat transfer fluid from the manifold outlet 508 is pumped to a cooling component, such as a radiator, to remove a portion of the heat transferred to the heat transfer fluid, and the heat transfer fluid is returned to the manifold inlet 506.

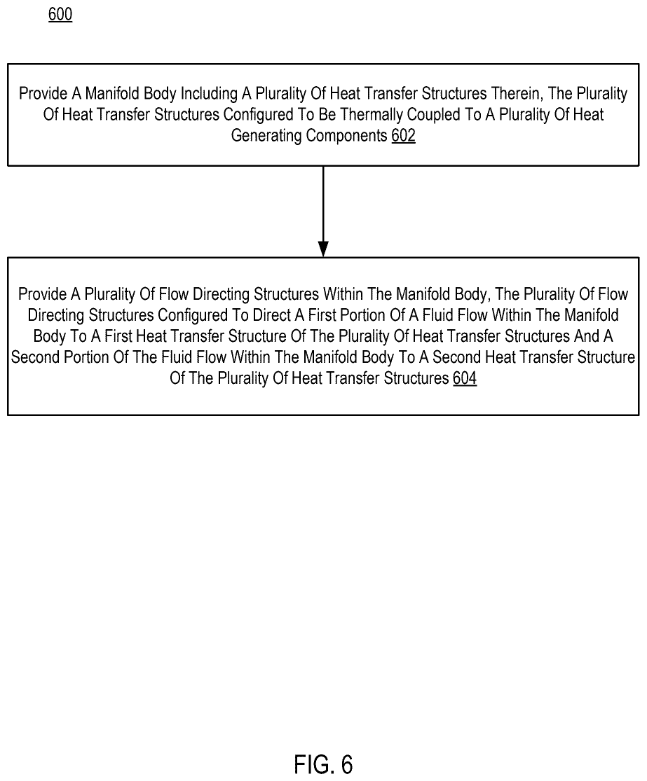

FIG. 6 sets forth a flow chart of an example process 600 for multiple chip module direct attach cooling according to aspects of the present disclosure. The process 600 includes providing 602 a manifold body including a plurality of heat transfer structures therein. The plurality of heat transfer structures are configured to be thermally coupled to a plurality of heat generating components. In a particular embodiment, the manifold body is configured to be compliant under a distributed pressure load when thermally coupled to the plurality of heat generating components.

The process 600 further includes providing 604 a plurality of flow directing structures within the manifold body. The plurality of flow directing structures are configured to direct a first portion of a fluid flow within the manifold body to a first heat transfer structure of the plurality of heat transfer structures and a second portion of the fluid flow within the manifold body to a second heat transfer structure of the plurality of heat transfer structures. In an embodiment, at least one of the plurality of heat transfer structures is configured to be coupled to a first portion of at least one of the plurality of heat generating components. In a particular embodiment, the first portion comprises a higher heat load area of the at least one of the plurality of heat generating components.

Various aspects of the present disclosure are described by narrative text, flowcharts, block diagrams of component cooling device embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. An apparatus comprising:
a manifold body including a plurality of heat transfer structures therein, the plurality of heat transfer structures configured to be thermally coupled to a plurality of heat generating components; and
a plurality of flow directing structures within the manifold body, the plurality of flow directing structures configured to direct a first portion of a fluid flow within the manifold body to a first heat transfer structure of the plurality of heat transfer structures and a second portion of the fluid flow within the manifold body to a second heat transfer structure of the plurality of heat transfer structures.

2. The apparatus of claim 1, wherein the manifold body is configured to be compliant under a distributed pressure load when thermally coupled to the plurality of heat generating components.

3. The apparatus of claim 1, wherein the plurality of heat transfer structures is configured to distribute a mechanical load from a first side of the manifold body to a second side of the manifold body.

4. The apparatus of claim 1, wherein at least one of the plurality of heat transfer structures is configured to be coupled to a first portion of at least one of the plurality of heat generating components.

5. The apparatus of claim 4, wherein the first portion comprises a higher heat load area of the at least one of the plurality of heat generating components.

6. The apparatus of claim 4, wherein the at least one of the plurality of heat generating components comprises a processor.

7. The apparatus of claim 6, wherein the first portion of the at least one of the plurality of heat generating components comprises a core area of the at least one heat generating component.

8. The apparatus of claim 1, wherein the plurality of heat transfer structures comprises a first heat transfer structure and a second heat transfer structure, and the first heat transfer structure has a different heat transfer characteristic than the second heat transfer structure.

9. The apparatus of claim 1, wherein the plurality of heat transfer structures comprises a first heat transfer structure and a second heat transfer structure and the first heat transfer structure has a different pressure drop characteristic than the second heat transfer structure.

10. The apparatus of claim 1, wherein at least one of the plurality of flow directing structures comprises a permeable mesh.

11. The apparatus of claim 1, wherein at least one of the plurality of flow directing structures comprises a rigid wall.

12. The apparatus of claim 1, wherein the manifold body is configured to be directly coupled to the plurality of heat generating components.

13. The apparatus of claim 1, wherein the plurality of heat generating components comprise a first heat generating component and a second heat generating component, wherein the first heat generating component is arranged orthogonally to the second heat generating component.

14. The apparatus of claim 1, wherein at least one of the plurality of flow directing structures includes an opening.

15. The apparatus of claim 1, wherein each of the plurality of heat generating components comprises a chip.

16. A method comprising:
providing a manifold body including a plurality of heat transfer structures therein, the plurality of heat transfer structures configured to be thermally coupled to a plurality of heat generating components; and
providing a plurality of flow directing structures within the manifold body, the plurality of flow directing structures configured to direct a first portion of a fluid flow within the manifold body to a first heat transfer structure of the plurality of heat transfer structures and a second portion of the fluid flow within the manifold body to a second heat transfer structure of the plurality of heat transfer structures.

17. The method of claim 16, wherein the manifold body is configured to be compliant under a distributed pressure load when thermally coupled to the plurality of heat generating components.

18. The method of claim 16, wherein at least one of the plurality of heat transfer structures is configured to be coupled to a first portion of at least one of the plurality of heat generating components.

19. The method of claim 18, wherein the first portion comprises a higher heat load area of the at least one of the plurality of heat generating components.

20. The method of claim 16, wherein the plurality of heat transfer structures comprise a first heat transfer structure and a second heat transfer structure, and the first heat transfer structure has a different heat transfer characteristic than the second heat transfer structure.
